(19) United States
(12) Patent Application Publication
(10) Pub. No.: US 2024/0357822 A1
(43) Pub. Date: Oct. 24, 2024

(54) NANOWIRE FLASH MEMORY WITH SEPARATED SOURCE/DRAIN REGIONS

(71) Applicant: International Business Machines Corporation, Armonk, NY (US)

(72) Inventors: Min Gyu Sung, Latham, NY (US); Julien Frougier, Albany, NY (US); Ruilong Xie, Niskayuna, NY (US); Chanro Park, Clifton Park, NY (US); Juntao Li, Cohoes, NY (US)

(21) Appl. No.: 18/305,653

(22) Filed: Apr. 24, 2023

(51) Int. Cl. H10B 43/35; H01L 23/528; H01L 25/065; H01L 29/06; H01L 29/423; H01L 29/66; H01L 29/775; H01L 29/786; H10B 41/27; H10B 41/35; H10B 43/27; H10B 80/00

(52) U.S. Cl. CPC H10B 43/35; H01L 23/5283; H01L 25/0657; H01L 29/0673; H01L 29/42392; H01L 29/66439; H01L 29/66545; H01L 29/775; H01L 29/78696; H10B 41/27; H10B 41/35; H10B 43/27; H10B 80/00

(57) ABSTRACT

A memory device including a stack of nanostructures, a first plurality of nanosheets/nanowires from the stack of nanostructures having first source and drain regions at their opposing ends to position first channel regions for a first memory cell, and a second plurality of nanosheets/nanowires from the stack of nanostructures having second source and drain regions at their opposing ends to position second channel regions for a second memory cell. An isolation liner layer is present between the first source and drain regions and the second source and drain regions. The memory device further includes a shared gate all around (GAA) control gate for the first and second memory cell, the shared gate all around (GAA) control gate including tunnel dielectric layer on the first and second channel regions, a trap dielectric layer on the tunnel dielectric layer, and a control conductor on the trap dielectric layer.

### BACKGROUND

The present disclosure relates to memory devices, and more particularly to memory devices including channel regions integrated within nanosheets.

NOR (Not Or) flash memory flash memory is one of two types of non-volatile storage technologies, in which NAND (Not And) is the other. Non-volatile memory doesn't require power to retain data. NOR and NAND use different logic gates, which can be referred to as the fundamental building block of digital circuits, in each memory cell to map data. NOR flash is faster to read than NAND flash, but it's also more expensive and it takes longer to erase and write new data. NAND has a higher memory capacity than NOR flash.

### SUMMARY

In one aspect, a memory device is provided that includes two memory devices that are stacked and employ nanostructures for channel regions.

In one embodiment, the nanostructures of the memory device are nanowires. For example, the memory device may include a stack of nanostructures. In some embodiments, a first plurality of nanowires from the stack of nanostructures have first source and drain regions at their opposing ends to position first channel regions for a first memory cell. In some embodiments, a second plurality of nanowires from the stack of nanostructures have second source and drain regions at their opposing ends to position second channel regions for a second memory cell. An
isolation liner layer is present between the first source and drain regions and the second source and drain regions. Further, a shared gate all around (GAA) control gate is positioned for the first and second memory cell. The shared gate all around (GAA) control gate includes a tunnel dielectric layer on the first and second channel regions, a trap dielectric layer on the tunnel dielectric layer, and a control conductor on the trap dielectric layer.

In one embodiment, the nanostructures of the memory device are nanosheets. For example, the memory device may include a stack of nanostructures. In one embodiment, the memory device includes a first plurality of nanosheets from the stack of nanostructures having first source and drain regions at their opposing ends to position first channel regions for a first memory cell. In one embodiment, the memory device includes a second plurality of nanosheets from the stack of nanostructures having second source and drain regions at their opposing ends to position second channel regions for a second memory cell. An isolation liner layer is present between the first source and drain regions and the second source and drain regions. In one embodiment, the memory device further includes a shared gate all around (GAA) control gate for the first and second memory cell, the shared gate all around (GAA) control gate includes tunnel dielectric layer on the first and second channel regions, a trap dielectric layer on the tunnel dielectric layer, and a control conductor on the trap dielectric layer.

In another aspect, a method of forming a memory device is provided. In one embodiment, the method of forming the memory device includes forming a replacement gate structure on a channel portion of a stack of nanostructures, and forming trenches in a stack of nanostructures, wherein the channel portion of the stack of nanostructures is between the trenches. The method further includes forming a first source and drain semiconductor material at a first height in the trenches in contact with a first set of nanostructures for a first memory cell, and forming an isolation layer on the first source and drain semiconductor material that is at the first height. The method may further include forming a second source and drain semiconductor material at a second height in the trenches in contact with a second set of nanostructures for a second memory cell, and substituting the replacement gate structure with a shared gate all around (GAA) control gate for the first and second memory cell. In some embodiments, the shared gate all around (GAA) control gate includes a tunnel dielectric layer on the channel portion of the stack of nanostructures, a trap dielectric layer on the tunnel dielectric layer, and a control conductor on the trap dielectric layer.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a side cross-sectional view of a nanowire based high density NOR flash memory device with a separated source/drain region and a backside contact, in accordance with one embodiment of the present disclosure.

FIG. 2 is a side cross-sectional view of an initial structure that can be used in some embodiments of the present disclosure.

FIG. 3 is a side cross-sectional view illustrating forming the sacrificial structures that are employed for the replacement gate process used in forming the nanowire/nanosheet based high density NOR flash memory, in accordance with one embodiment of the present disclosure.

FIG. 4 is a side cross-sectional view illustrating one embodiment of a selective etch step for removing the layer of the initial semiconductor material that separates the semiconductor material stack that provides the nanostructures, e.g., nanowires and/or nanosheets, from the supporting substrate.

FIG. 5 is a side cross-sectional view illustrating forming a spacer abutting the replacement gate structure, an etch process applied to the stack of semiconductor material layers, the formation of an inner spacer, and forming the semiconductor material for the source and drain regions of the first memory cell, in accordance with one embodiment of the present disclosure.

FIG. 6 is a side cross-sectional view illustrating forming a block mask structure and recessing the semiconductor material for the source and drain regions of the first memory cell, in accordance with one embodiment of the present disclosure.

FIG. 7 is a side cross-sectional view illustrating removing the block mask structure and forming a liner of dielectric material for the isolation liner layer that separates the first memory cell from the second memory cell, in accordance with one embodiment of the present disclosure.

FIG. 8 is a side cross-sectional view depicting one embodiment of depositing an organic planarization layer (OPL) filling the trenches, recessing the organic planarization layer (OPL) to expose the sidewalls of the first and second semiconductor material layer in the portions of the trenches having a height corresponding to the second memory cell, and removing the portion of the isolation liner layer that are present on the sidewalls of the first and second semiconductor material layer in the portions of the trenches having a height corresponding to the second memory cell.

FIG. 9 is a side cross-sectional view illustrating forming the semiconductor material for the source and drain regions of the second memory cell, in accordance with one embodiment of the present disclosure.

FIG. 10 is a side cross-sectional view illustrating removing the replacement gate structure and forming a shared gate all around (GAA) control gate, in accordance with one embodiment of the present disclosure.

FIG. 11 is a side cross-sectional view illustrating the shared gate all around (GAA) control gate structure depicted in FIG. 10.

FIG. 12 is a side cross-sectional view illustrating forming the metal lines and vias providing electrical contact to the contacts that are in electrical communication with the source and drain regions of the second memory cell.

FIG. 13 is a side cross-sectional view one embodiment of flipping the structure depicted in FIG. 12, removing the supporting substrate, and forming an interlevel dielectric layer through which the electrical communication structures to the first memory cell are ultimately formed.

FIG. 14 is a side cross-sectional view illustrating forming the metal lines and vias providing electrical contact to the contacts that are in electrical communication with the source and drain regions of the second memory cell, and operation of current path for the first memory cell, in accordance with one embodiment of the present disclosure.

FIG. 15 is a side cross section view illustrating operation of current path for the second memory cell.

### DETAILED DESCRIPTION

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

In one aspect, embodiments of the present disclosure describe structures and methods for nanostructure based high density NOR flash memory with separated source/drain regions and a backside contact. NOR flash memory has a faster read speed than NAND flash memory, and can read and edit more precisely. For example, NOR flash memory can do byte access. However, NOR flash memory comes at a higher price point per byte when compared to NAND flash memory due to low density cell. In some instances, a user may choose NOR flash memory mostly for executing code. In contrast to NOR flash memory, NAND flash memory has a slower read speed and can only access memory in blocks rather than bytes, and NAND flash memory is generally cheaper than NOR flash memory.

Some explanation of how NOR flash memory can operate may include that programing a NOR memory cell, i.e., setting it to logical 0, via hot-electron injection can include applying an elevated on-voltage (e.g., greater than 5V) that is applied to the control gage (CG). With the control gate (CG) now ON, electrons can flow from the source to the drain, e.g., in an N-type transistor. The source-drain current is sufficiently high to cause some high energy electrons to jump through the insulating layer onto the floating gate (FG), via a process that is called hot-electron injection. Another operation of NOR flash memory is erasure via tunneling. To erase a NOR flash cell, e.g., resetting it to the “1” state, a large voltage of the opposite polarity is applied between the control gate (CG) and the source terminal, which pulls the electrons off the floating gate (FG) through quantum tunneling.

In some embodiments, NOR flash memory chips are divided into erase segments, which may be referred to as blocks. In this example, the erase operations can be performed only on a block wise basis. All the cells in an erase segment must be erased together. Programming of NOR cells, however, generally can be performed one byte or word at a time.

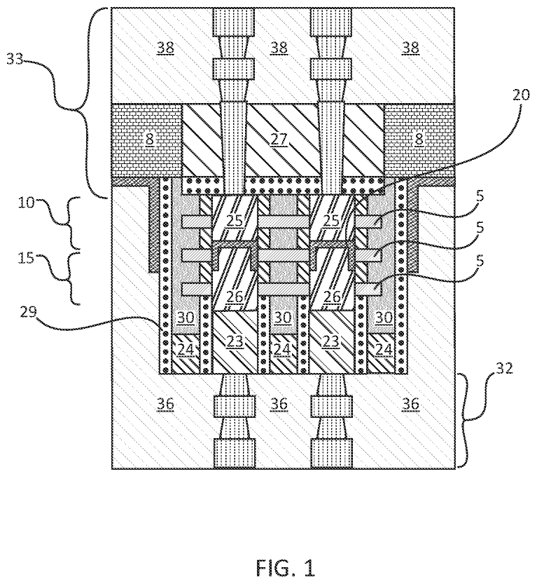

As will be described in greater detail below, the methods and structures of the present disclosure include two memory cells, i.e., one memory cell that is located on the frontside of the device, and a second memory cell that is located on the backside of the device. The memory device structures described herein are based on a nanowire/nanosheet transistors; in which the memory channel and the memory cells are formed in the same process sequence. In this example, the backside of the device is used for the structures of the second memory cell that are formed using back end of the line (BEOL) processes. The structures and methods described herein can increase device density in NOR flash memory by stacking devices, employing nanostructure channel regions, and employing a shared gate all around (GAA) control gate. The methods and structures of the present disclosure are now described with reference to FIGS. 1-15.

FIG. 1 illustrates one embodiment of a nanostructure based high density NOR flash memory device with a separated source/drain and backside contact. The depicted structure includes multiple, e.g., two, NOR memory cells that are formed by nanowire/nanosheet channel. A “nanosheet” is a two-dimensional nanostructure with thickness in a scale ranging from 1 nm to 100 nm. A “nanowire” is similar to a nanosheet, yet has a substantially circular or oblong cross-section. The nanostructures, e.g., nanowire or nanosheet, that are used for the channel regions of the memory cells are identified by reference number 5 in FIG. 1.

FIG. 1 illustrates two memory cells, e.g., a first memory cell 10 and a second memory cell 15. Each of the first and second memory cells 10, 15 are isolated from one another by an isolation liner layer 20 that is positioned therebetween. Further, each of the first memory cell 10 and the second memory cell 15 have a set of source and drain regions. In some embodiments, each of the NOR memory cells 10, 15 are controlled using a shared control gate 30. In some embodiments, the shared control gate 30 may be a gate all around (GAA) type gate structure, in which the channel direction is parallel to the upper surface of the supporting substrate on which the first and second memory cells 10, 15 are positioned.

Still referring to FIG. 1, in some embodiments, the first source and drain regions 25 for the first memory cell 10 are contacted by a series of contacts identified by reference number 33 that are separated from the contacts 32 to the second source and drain region 26 of the second memory cell 15. In the embodiment illustrated in FIG. 1, the contacts 32 to the second memory cell 15 are formed using back end of the line (BEOL) processing, e.g., the process steps employed for back side power delivery network (BSPDN). The stacked arrangement of the first and second memory cells 10, 15 using nanostructure channel regions provides a high density NOR memory device.

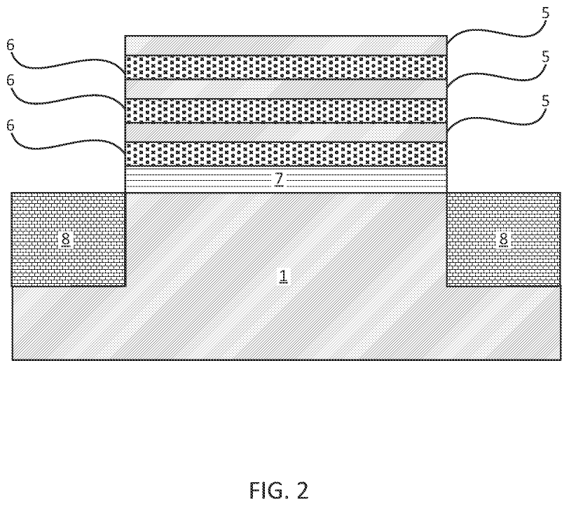

The elements depicted in FIG. 1 are now described in greater detail in the following description of one embodiment of a method that can be used to provide the structure depicted in FIG. 1. In some embodiments, the method may include forming the front end of the line (FEOL) gate all around field effect transistor (GAA-FET) (also referred to as first memory cell 10), which can be followed by forming the isolation liner layer 20 that is positioned separating the first memory cell 10 from the subsequently formed second memory cell 15. In a following step, the second memory cell 15 is formed atop the isolation liner layer 20. The second memory cell 15 can be formed as part of a back end of the line (BEOL) process sequence. Contacts 33 may then be formed to the first memory cell 10. This may include process steps for the back side power delivery network (BSPDN). This can include milling the back side of the substrate, e.g., until reaching the base of the shallow trench isolation (STI) regions 8. The method may continue with back end of the line (BEOL) processing. The aforementioned process sequence is now described with greater detail with reference to FIGS. 2-15.

FIG. 2 illustrates one embodiment of an initial structure that can be used in some embodiments of the present disclosure. In the embodiment depicted in FIG. 2, a stack of semiconductor material layers 5, 6 that are present atop a supporting substrate 1. The semiconductor material layers 5,6 are ultimately processed to provide nanostructures, e.g., nanosheets or nanowires. Further, shallow trench isolation regions 8 are present on opposing sides of the stack of semiconductor material layers 5, 6. In some embodiments, each stack of semiconductor material layers 5, 6 includes at least two layers of different semiconductor material compositions, e.g., alternating compositions, that are present overlying the substrate 1. The substrate 1 may be composed of a supporting material, such as a semiconductor material, e.g., silicon, or dielectric material, such as silicon oxide or silicon nitride.

In the embodiment depicted in FIG. 1, the stack of semiconductor material layers 5, 6 includes a repeating sequence of two semiconductor material layers having different compositions. For example, the first semiconductor material 5 may be composed of a germanium free silicon containing semiconductor material, such as silicon (Si), whereas the second semiconductor material 6 that is present on the first semiconductor material 5 may be composed of a silicon and germanium containing semiconductor material, such as silicon germanium (SiGe). It is noted that this is only one example of semiconductor materials that may be used for the at stack of semiconductor material layers 5, 6. Any semiconductor material composition may be used for each of the at least two semiconductor materials so long as at least one of the compositions selected allow for selective etching between at least two of them. Any type IV semiconductor composition combination and/or III-V semiconductor composition combination is suitable for use with the present disclosure. For example, the compositions selected for the at least two semiconductor materials include Si, SiGe, SiGeC, SiC, single crystal Si, polysilicon, i.e., polySi, epitaxial silicon, i.e., epi-Si, amorphous Si, i.e., α:Si, germanium, gallium arsenide, gallium nitride, cadmium telluride and zinc sellenide.

The stack of the layered semiconductor materials may be formed using a deposition process, such as epitaxial deposition. “Epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. The thickness of each of the at least two semiconductor material layers 5, 6 may range from 1 nm to 30 nm. In another embodiment, the thickness of each of the at least two semiconductor material layers 5,6 may range from 5 nm to 20 nm.

It is noted that in the embodiment depicted in FIG. 2, the stack also includes an initial sacrificial semiconductor layer 7. The initial sacrificial semiconductor layer 7 may be composed of a silicon and germanium containing composition material, in which the germanium content of the initial sacrificial semiconductor layer 7 is different from the germanium concentration of the second semiconductor material 6. For example, the initial sacrificial semiconductor layer 7 may be composed of silicon germanium (SiGe) having a germanium content of 55 wt. %, while the germanium content of the second semiconductor material 6 is silicon germanium (SiGe) having a germanium content of 25 wt. %. Further, the first semiconductor material 5 in this example does not include germanium (Ge), and may be 100 wt. % silicon (Si).

The semiconductor material layers 5, 6 may be patterned to provide the geometry of the stack. In some embodiments, the semiconductor material layers 5, 6 may be patterned using deposition, photolithography and subtractive etch processing. In one example, the stack may have a height ranging from 5 nm to 200 nm, and a width ranging from 5 nm to 60 nm.

In the following description, the semiconductor material layers identified by reference numbers 5 may also be referred to as “nanosheets” or “nanowires” following processing to reduce the materials to nano-dimensions, and the semiconductor material layers identified by reference numbers 6 may be referred to as “sacrificial nanostructures”.

Isolation regions 8 may be composed of a dielectric material, e.g., silicon oxide. The isolation regions 8 may be formed using a deposition process, such as chemical vapor deposition (CVD).

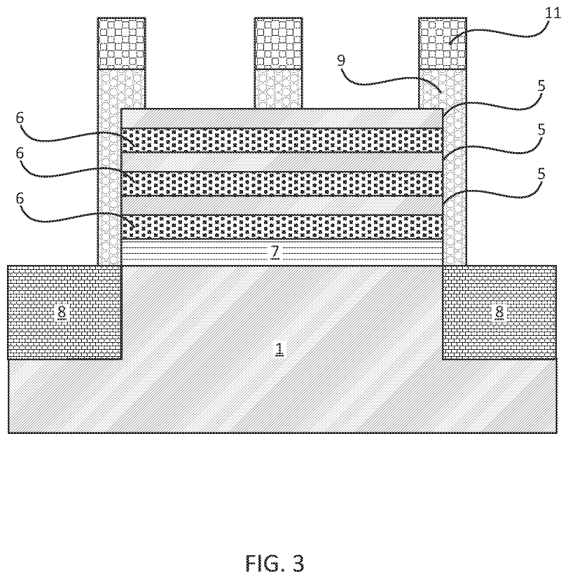

FIG. 3 illustrates one embodiment of the sacrificial gate structures 9, 11 that are employed for the replacement gate process used in forming the nanowire/nanosheet based high density NOR flash memory with separated source/drain and backside contact. By “replacement” it is meant that the structure is present during processing of the semiconductor device, but is removed from the semiconductor device prior to the device being completed. As used herein, the term “replacement gate structure” denotes a sacrificial structure that dictates the geometry and location of the later formed functioning gate structure.

In one embodiment, the sacrificial material 9 that provides the sacrificial gate electrode of the replacement gate structure may be composed of any material that can be etched selectively to the at least one of the material layers of the stacks of the at least two semiconductor materials 5, 6, 7, i.e., the stacks of the layers provided by the first semiconductor material 5, second semiconductor material 6 and initial sacrificial semiconductor layer 7. In one embodiment, the sacrificial material 9 of the replacement gate structure may be composed of a silicon-including material, such as polysilicon. In another embodiment, the sacrificial material 9 replacement gate structure may be composed of a dielectric material, such as an oxide, nitride or oxynitride material, or amorphous carbon. The replacement gate structure may be formed using deposition (e.g., chemical vapor deposition) photolithography and etch processes (e.g., reactive ion etching). In some embodiments, a mask structure may be employed as illustrated by reference number 11. The mask structure 11 may be provided using deposition and photolithography steps, and may be employed in combinations with the directional, i.e., anisotropic, etch processes to shape the geometry of the replacement gate structure that is composed of the sacrificial material 9.

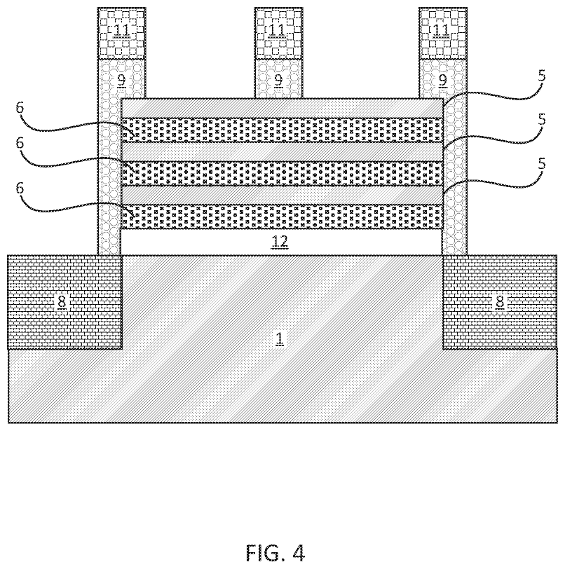

FIG. 4 illustrates one embodiment of a selective etch step for removing the layer of the initial sacrificial semiconductor layer 7 that separates the stack that ultimately provides the nanostructures, e.g., nanowires and/or nanosheets, from the supporting substrate 1. Removing the initial sacrificial semiconductor layer 7 produces a space 12 separating the stack of semiconductor material layers 5, 6 from the supporting substrate 1. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 10:1 or greater, e.g., 1000:1. For example, the etch process may remove the silicon and germanium (SiGe) containing material having a germanium content of 55 wt. % of the initial sacrificial semiconductor layer 7 without removing the second semiconductor material 6, e.g., composed of a silicon and germanium (SiGe) containing material having a germanium (Ge) content of 25 wt. %, and the first semiconductor material 5 of silicon (Si), as well as not removing the supporting substrate 1 and the material of the replacement gate structure, e.g., sacrificial gate material 9 and mask structure 11.

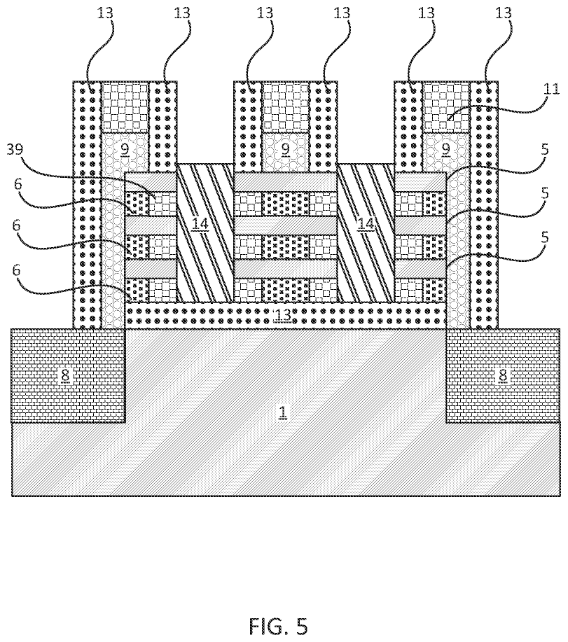

FIG. 5 illustrates forming a spacer 13 abutting the replacement gate structure, an etch process applied to the stack of semiconductor material layers 5, 6, the formation of an inner spacer 29, and forming the semiconductor material 14 for the source and drain regions 25 of the first memory cell 10.

The spacer identified by reference number 13 is formed using deposition and etch back processes. For example, the spacer 13 may be composed of a dielectric material, such as silicon nitride or silicon oxide, and may be formed using a deposition process, such as chemical vapor deposition (CVD). The spacer 13 that is abutting the replacement gate structure 9,11 also fills the space between the stack of the first and second semiconductor material layer 5, 6 that is formed by removing the initial semiconductor layer 7. In some embodiments, following deposition of the material for the spacer, and etch back process, such as reactive ion etching (RIE) may be employed to further tailor the geometry of the spacer.

Following the formation of the spacer 13, the exposed portions of the stack of first and second semiconductor material layers 5, 6 may be etched. The etch process for etching the stack of first and second semiconductor material layers 5, 6 may be an anisotropic etch, such as reactive ion etching (RIE), that terminates on the portion of the spacer 13 that fills the space 12 between the stack of the first and second semiconductor material layer 5, 6 that is formed by removing the initial sacrificial semiconductor layer 7. The etch process for etching the stack of first and second semiconductor material layers 5, 6 may be referred to as a nanostructure etch back.

Still referring to FIG. 5, following the nanostructure etch back that is applied to the stack of the first and second semiconductor material layers 5, 6, the inner spacer 39 may then be formed. The nanostructure etch back forms trenches in the stack of first and second semiconductor material layers 5, 6, in which the sidewall of the trenches are provided by the alternating first and second semiconductor material layers 5, 6 along the height of the trench formed through the stack. Forming the inner spacer 39 can begin with forming a divot in the sidewall of the trenches, e.g., by laterally etching one of the first and second semiconductor material layers 5, 6 selectively to the other of the first and second semiconductor material layers 5, 6. In the example, depicted in FIG. 5, an isotropic etch, such as a plasma etch or gas phase etch, may laterally etch the first semiconductor material layer 5 relative to the second semiconductor material layer 6 forming a plurality of recesses or divots on the sidewalls of the trenches etched into the stack of the first and second semiconductor material layers 5, 6.

A dielectric material is then formed in the recesses or divots that have been formed on the sidewalls of the trenches. The dielectric material is first deposited filling the recesses or divots, and is then etched to provide that the dielectric material remains within the recesses and divots forming the inner spacers 39, yet is removed from the portions of the structure that are outside the recesses or divots. In one embodiment, a conformal dielectric layer for inner spacer 39 formation is deposited on the sidewalls of the trench that are formed by patterning the stack of nanosheets. The term “conformal” denotes a layer having a thickness that does not deviate from greater than or less than 30% of an average value for the thickness of the layer. The conformal dielectric layer may be blanket deposited to be on the upper and sidewall surfaces of the trenches. The conformal dielectric layer may be an oxide, nitride or oyxnitride material. In one example, the conformal dielectric layer is composed of silicon oxide. The conformal dielectric layer may be deposited using a conformal deposition process, such as chemical vapor deposition, such as plasma enhanced chemical vapor deposition or metal organic chemical vapor deposition. The conformal dielectric layer may also be deposited using atomic layer deposition (ALD). Following deposition of the conformal dielectric layer, a directional etch, such as reactive ion etching (RIE), is used to remove the portions of the conformal dielectric layer that are not present in the divots/recessed, which forms the inner spacers 39.

FIG. 5 further illustrates forming the semiconductor material 14 for the first source and drain regions 25 of the first memory cell 10. As used herein, the term “drain” means a doped region in semiconductor device located at the end of the channel region, in which carriers are flowing out of the transistor through the drain. The term “source” is a doped region in the semiconductor device, in which majority carriers are flowing into the channel region. The source and drain regions may be composed of epitaxial semiconductor material that is doped to an n-type or p-type dopant. The term “epitaxial semiconductor material” denotes a semiconductor material that has been formed using an epitaxial deposition or growth process. “Epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

In some embodiments, the epitaxial semiconductor material that provides the source and drain regions may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs). The epitaxial semiconductor material for the source and drain regions is doped to provide the conductivity type. For example, the source and drain regions may be insitu doped. By “in situ” doping it is meant that the dopant is introduced to the base material through dopant gasses that are mixed with the gasses for depositing the base material during the epitaxial deposition process. As noted, the semiconductor material 14 for the first source and drain regions 25 of the first memory cell 10 may be n-type or p-type doped.

In the embodiment that is depicted in FIG. 5, the epitaxial growth process continues until the semiconductor material for the first source and drain regions 25 of the first memory cell 10 fills the entirety of the trenches that were formed by etching through the stack of the first and second semiconductor material layers 5, 6. The sidewalls of the first and second semiconductor material layer 5, 6 that are exposed by the etch process for forming the trenches provides the site for epitaxial growth, in which the semiconductor material grows laterally from the sidewalls until the trenches are formed.

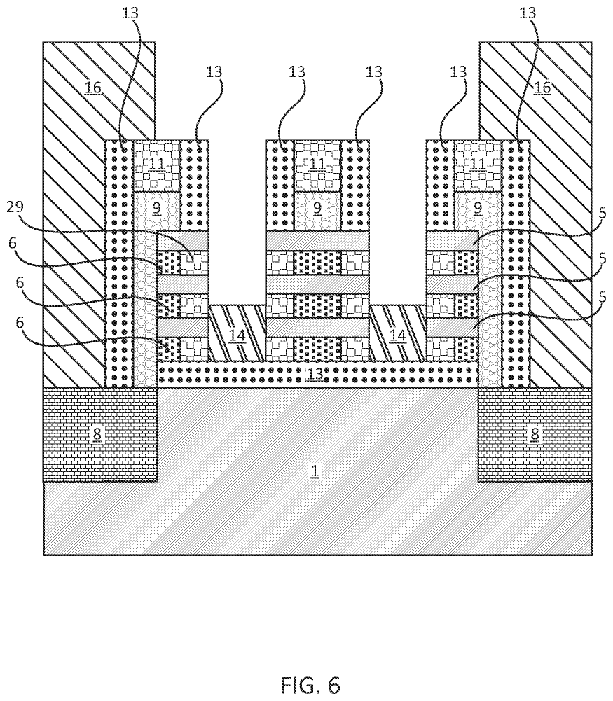

FIG. 6 illustrates forming a block mask structure 16 and recessing the semiconductor material 14 for the first source and drain regions 25 of the first memory cell 10. More particularly, the semiconductor material is recessed to the height of the first memory cell 10, in which the semiconductor material for the second source and drain regions 26 of the second memory cell 15 is subsequently formed atop the first memory cell 10.

The block mask structure 16 may comprise soft and/or hardmask materials and can be formed using deposition, photolithography and etching. In one embodiment, the block mask structure 16 comprises an organic planarization layer (OPL). A block mask including an OPL material may be formed by blanket depositing a layer of OPL material; providing a patterned photoresist atop the layer of OPL material; and then etching the layer of POL material to provide the block mask structure 16.

Following the formation of the block mask structure 16, an etch process is performed recessing the semiconductor material for the first source and drain regions 25 of the first memory cell 10. In one embodiment, a directional etch process, such as reactive ion etching (RIE), may be employed to etch the exposed portions the semiconductor material for the first source and drain regions 25 of the first memory cell 10.

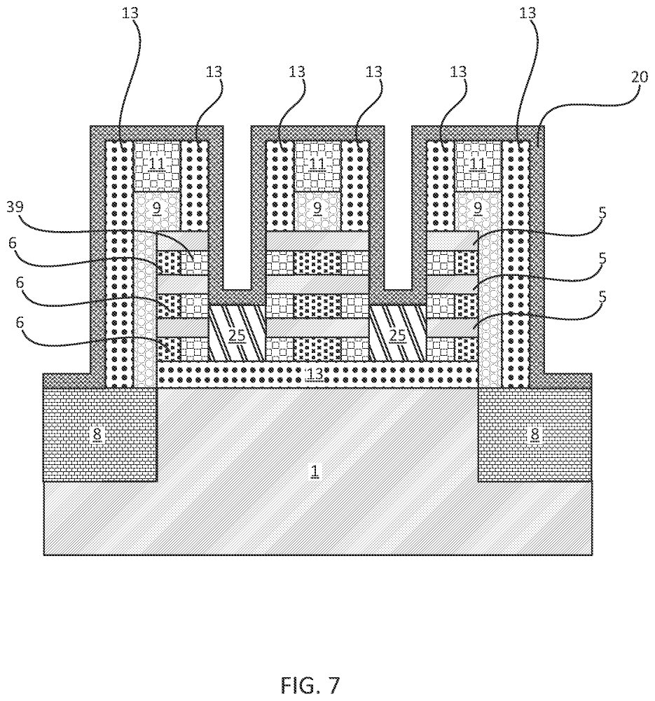

FIG. 7 illustrates removing the block mask structure 16 that is depicted in FIG. 6, and forming a liner of dielectric material for the isolation liner layer 20 that separates the first memory cell 10 from the second memory cell 15. For example, the block mask structure 16 may be removed using selective etching, chemical stripping and/or oxygen ashing. With the block mask structure 16 removed, a blanket deposition of the material for the isolation liner layer 20 may be performed. The isolation liner layer 20 may have a conformal thickness, e.g., be a conformally deposited layer. The isolation liner layer 20 may be deposited using a chemical vapor deposition process, such as plasma enhanced chemical vapor deposition (PECVD) or metal organic chemical vapor deposition (MOCVD). The isolation liner layer 20 may also be deposited using atomic layer deposition (ALD). In one example, the isolation liner layer 20 is composed of silicon nitride.

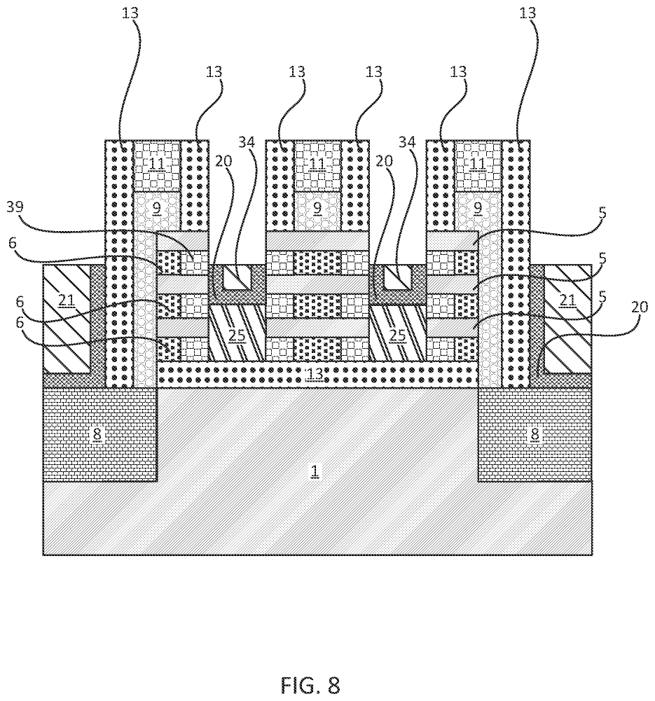

FIG. 8 illustrates depositing an organic planarization layer (OPL) filling the trenches, recessing the organic planarization layer (OPL) to expose the sidewalls of the first and second semiconductor material layer 5, 6 in the portions of the trenches having a height corresponding to the second memory cell 15, and removing the portion of the isolation liner layer 20 that are present on the sidewalls of the first and second semiconductor material layer 5, 6 in the portions of the trenches having a height corresponding to the second memory cell 15. The organic planarization layer (OPL) 34 is deposited using a deposition process such as spin on deposition or chemical vapor deposition (CVD).

The organic planarization layer (OPL) layer 34 may be composed of an organic polymer that may include polyacrylate resin, epoxy resin, phenol resin, polyamide resin, polyimide resin, unsaturated polyester resin, polyphenylenether resin, polyphenylenesulfide resin, or benzocyclobutene (BCB). In some embodiments, the organic planarization layer (OPL) 34 is deposited from solution, e.g., by spin on deposition, and is baked at high temperature.

The organic planarization layer (OPL) 34 can then be recessed using a directional etch, e.g., reactive ion etching (RIE) that is timed to provide the correct height for the recessed organic planarization layer. The recessed organic planarization layer (OPL) 34 functions as an etch mask in the subsequent step for etching the isolation liner layer 20. Therefore, the recessed organic planarization layer 34 is set to a height that allows or the isolation liner layer 20 to be recessed in a manner that exposes a sidewall of the etched first and second semiconductor material layers 5, 6 that is used for epitaxial growth of the semiconductor material for the source and drain regions of the second memory cell 15. Following the process sequence that produces the recessed organic planarization layer (OPL) 34, the isolation liner layer 20 is recessed by removing the unprotected portion of the liner with an anisotropic etch, such as reactive ion etching (RIE). When viewed from a side cross-sectional view as illustrated in FIG. 8, the isolation liner layer 20 has a U-shaped geometry that includes a horizontally orientated portion in direct contact with the first source and drain region 25, and vertically orientated portions that extend along the sidewalls of the trenches in which the conformal layer for the isolation liner layer 20 is deposited.

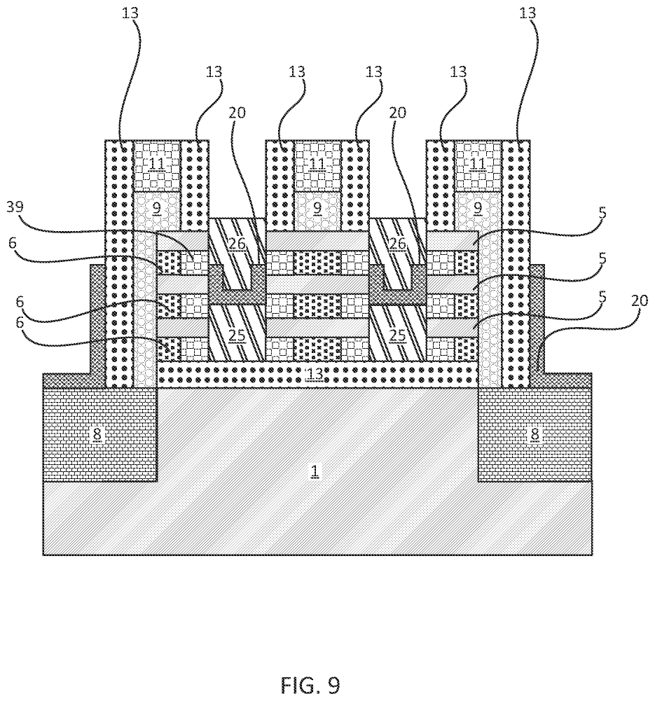

FIG. 9 illustrates forming the semiconductor material for the second source and drain regions 26 of the second memory cell 15. In some embodiments, the recessed organic planarization layer (OPL) 34 may be removed prior to the deposition of the semiconductor material for the second source and drain regions 26. The recessed organic planarization layer (OPL) 34 may be removed using selective etching, chemical stripping or ashing.

Following removal of the recessed organic planarization layer (OPL), the semiconductor material for the second source and drain regions 26 may be formed using an epitaxial deposition/growth process. In some embodiments, the epitaxial semiconductor material that provides the second source and drain regions 26 may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs).

The semiconductor material for the second source and drain regions 26 of the second memory cell 15 may be formed using epitaxial growth and/or deposition. The epitaxial semiconductor material for the source and drain regions is doped to provide the conductivity type. The second source and drain regions 26 may be composed of epitaxial semiconductor material that is doped to an n-type or p-type dopant. For example, the source and drain regions may be in situ doped. By “in situ” doping it is meant that the dopant is introduced to the base material through dopant gases that are mixed with the gasses for depositing the base material during the epitaxial deposition process.

The second source and drain regions 26 having two portions with different widths. A narrower portion of the second source and drain regions 26 fills the space between the vertically orientated portions of the U-shaped geometry for the isolation liner layer 20. A wider portion of the second source and drain regions 26 is present outside the portion of the structure including the U-shaped isolation liner layer 20.

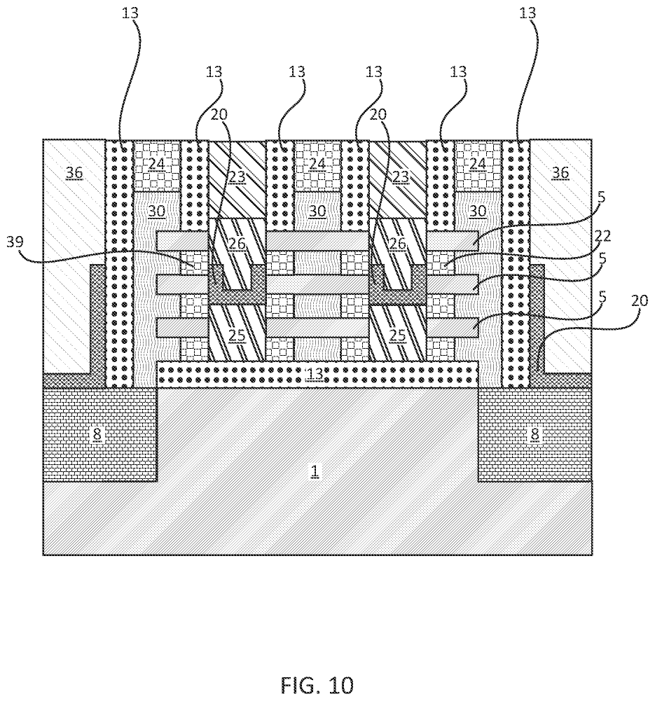

FIG. 10 illustrates removing the replacement gate structure and forming a shared control gate 30. This process sequence may be referred to as substituting the shared control gate 30 for the replacement gate structure. The term “shared” when referring to the shared control gate 30 illustrates that the gate structure simultaneously contacts the channel regions for both the first and second memory cells 10, 15. In some embodiments, prior to removing the replacement gate structure, a trench metal is deposited for the contacts to the second source and drain regions 26 of the second memory cell 15. The trench metal may be any conductive metal, such as copper, aluminum, etc. The trench metal for the contacts 23 may be deposited using plating, physical vapor deposition (PVD) or chemical vapor deposition (CVD).

In some embodiments, the process sequence for removing the replacement gate structure, e.g., including the sacrificial material 9 for the replacement gate structure and the mask structure identified by reference number 11, can begin with depositing an interlevel dielectric layer 36. The interlevel dielectric layer 36 may have a composition selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). The interlevel dielectric layer 36 may be deposited using a deposition process, such as spin on deposition (SOD) followed by a planarization process, such as chemical mechanical planarization (CMP). The planarization process may be continued until the upper surface of the interlevel dielectric layer 36 is coplanar with the upper surface of the mask structure identified by reference number 11 and the spacer 13 that is abutting the replacement gate structure 9.

The replacement gate structure 9, 11 may then be removed using a selective etch process. More particularly, removing the replacement gate structure using a selective etch process may include removing the sacrificial material 9 for the replacement gate structure and the mask structure identified by reference number 11, without removing the first and second semiconductor material layers 5, 6.

In some embodiments, once the sacrificial gate structure is removed, the first and second semiconductor material layers 5, 6 can be further processed to provide nanostructures, e.g., nanowires and/or nanosheets. For example, when the stack of first and second semiconductor material layers 5, 6 are further processed to provide nanowires, the second semiconductor material layers identified by reference number 6 may be removed selectively to the first semiconductor material layers identified by reference number 5. This provides a plurality of suspended first semiconductor material layers, which ultimately provided suspended channels. By “suspended channel” it is meant that at least one semiconductor material layer, e.g., first semiconductor material layer 5, is present overlying the substrate 1, wherein the sidewalls of the suspended channel are supported, e.g., anchored, in the spacer that was previously formed on the sidewall of the replacement gate structure, e.g., the spacer identified by reference number 13. The suspended channels may be nanosheets. The term “nanosheet” denotes a substantially two dimensional structure with thickness in a scale ranging from 1 to 100 nm. The width and length dimensions of the nanosheet may be greater than the width dimensions. A “nanowire” has an oblong or circular cross section of a dimension ranging from 1 to 100 nm.

In some embodiments, the suspended structure, e.g., first semiconductor material layer 5, may be further processed to a geometry in the nanometer regime. For example, the suspended first semiconductor material layers 5 may be thinned by a process that includes controlling thinning of the silicon (Si) containing nanosheets 5, which can include ozone (O₃) oxidation, SC1 chemistry oxidation and/or dry oxidation. In one embodiment, oxidation of the silicon containing surface of the exposed first semiconductor material layers 5 includes the application of ozone (O₃) gas at room temperature, e.g., 20°-25° C., or at elevated temperature.

In another embodiment, the controlled thinning of the first semiconductor material layers 5 can include the application of an SC-1 chemistry, which may be part of an RCA clean. For example, the first step of the RCA clean that includes ammonium hydroxide and hydrogen peroxide may be referred to as “SC-1” (standard clean #1). SC-1 may include of a mixture of ammonium hydroxide and hydrogen peroxide and deionized water. An example concentration ratio for the mix is 1:1:5 NH₄OH:H₂O₂:H₂O, although ratios as low as 0.05:1:5 are suitable for cleaning the substrate 5. SC-1 can operate in a temperature ranging from 50° C. to 70° C. The second step of the RCA clean that includes the aqueous mixture of hydrochloric acid and an oxidizing agent may be referred to as “SC-2” (standard clean #2). SC-2 includes a mixture of hydrochloric acid, hydrogen peroxide, and deionized water. An example concentration ratio for the mix is 1:1:5 HCl:H₂O₂:H₂O. In one embodiment, SC-2 is operated in the temperature range of 50-70° C.

In yet another example, the controlled oxidation may be provided by thermal oxidation, e.g., wet and/or dry thermal oxidation. Thermal oxidation of the first semiconductor material layer 5 can be performed at a temperature between 800° C. and 1200° C., resulting in so called High Temperature Oxide layer (HTO). In some embodiments, the thermal oxidation process may use either water vapor or molecular oxygen as the oxidant.

The aforementioned processes can form a thin oxide, e.g., silicon oxide (SiO₂), on the exposed surfaces of the silicon containing nanosheets 5, which can have a thickness ranging from 1 nm to 5 nm in thickness. In some embodiments, the thickness of the oxide formed on the exposed surfaces of the silicon containing nanosheets 5 can range from 1 nm to 2 nm. The oxide is formed on all exposed surfaces of the silicon containing nanosheets 5. The thickness of the oxide formed on the exposed surfaces of the silicon containing nanosheets can be conformal.

In some embodiments, following the formation of the oxide surface, e.g., thermal oxide, on the exposed surfaces of the first semiconductor material layer 5, an etch process may remove the oxide surface selectively to the non-oxidized portion of the first semiconductor material layer 5. For example, the etch process may remove the exposed oxide surface, e.g., thermal oxide, on the exposed surfaces of the first semiconductor material layer 5 selectively to the non-oxidized portion of the first semiconductor material layer 5 that is underlying the oxidized portion. The etch process may be a dry etch, or a wet etch. For example, reactive ion etch or plasma gas etching can remove the oxidized surfaces of the first semiconductor material layer 5 that are exposed. In some embodiments, removing the oxide reduces the dimensions of the nanosheets by 1 nm to 5 nm. For example, the dimensions may be reduced by width and height (thickness) by 1 nm to 5 nm. In another embodiment, removing the oxide reduces the dimensions of the nanosheets by 1 nm to 2 nm. Further, the etch processes may be adjusted to provide geometries for nanosheets and/or nanowires.

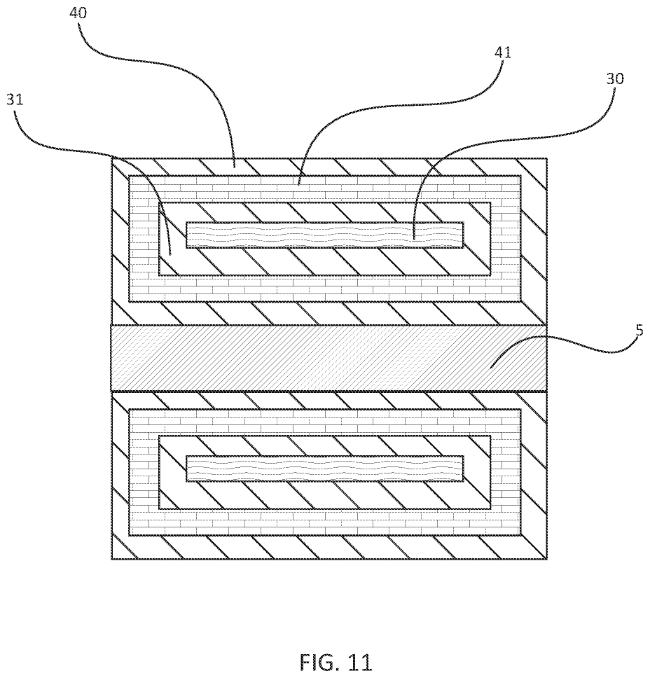

Referring to FIGS. 10 and 11, the method continues with the forming a gate structure for the memory cells including a shared control gate 30. As illustrated in FIG. 11, the gate structure includes a tunnel dielectric layer 40, e.g., tunnel oxide, that is formed directed on the suspended channel regions, e.g., suspended nanowires and/or suspended nanosheets. In some embodiments, the tunnel oxide is composed of silicon oxide (SiO₂). The next layer of the gate structure is a trap dielectric layer 41, e.g., nitride containing trap layer. The nitride containing trap layer is in direct contact with the tunnel oxide. The trap dielectric layer 41 may be composed of silicon nitride. The next layer of the gate structure may be an oxide containing blocking layer 31. The oxide containing block layer 31 may be in direct contact with the trap dielectric layer 41. In one example, the oxide containing block layer 31 may be composed of silicon oxide (SiO₂). The next layer of gate structure may be the shared control gate 30. The shared control gate 30 may be provided by doped polysilicon, e.g., n-type doped polysilicon. In this instance, the gate structure may be referred to as SONOS control gate, i.e., semiconductor/oxide/nitride/oxide/semiconductor control gate. Each of the aforementioned layers may be formed using a deposition method, such as chemical vapor deposition.

In another embodiment, the shared control gate 30 (also referred to as gate conductor) may be an elemental metal. For example, the shared control gate 30 may be composed of copper, aluminum, titanium, tantalum, titanium nitride, tantalum nitride and combinations thereof. The metal composition for the shared control gate 30 may be deposited using plating, chemical vapor deposition or physical vapor deposition.

As illustrated each channel region provided by the first semiconductor material 5, e.g., suspended channels being a nanostructure, such as a nanowire and/or nanosheet, has a gate all around (GAA) gate structure.

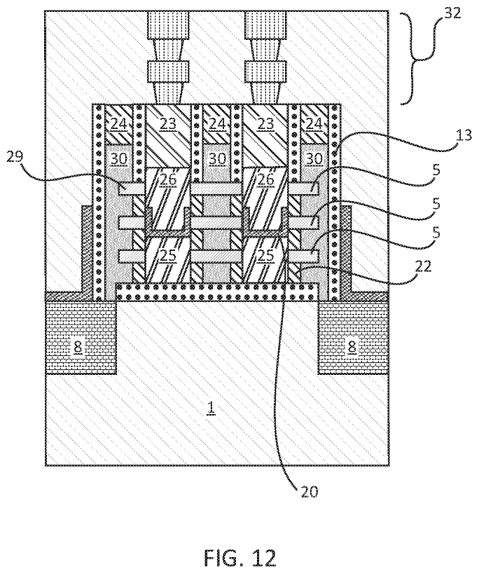

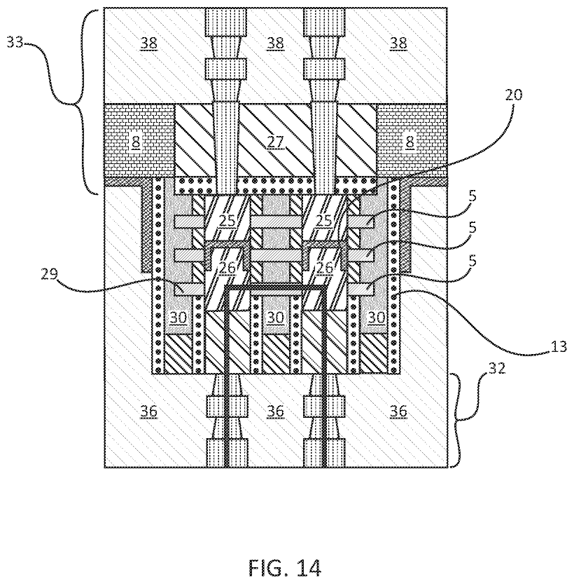

Referring to FIG. 12, the method continues with the forming the metal lines and vias collectively identified with reference number 32 providing contact to the contacts 23 that are in electrical communication with the source and drain regions 26 of the second memory cell 15. The process sequence that is used for forming the metal lines and vias is a back end of the line (BEOL) process. In some embodiments, an interlevel dielectric layer 36 is first deposited and then etched to form via openings to the underlying contacts 23. Thereafter, the via openings are then filled with an electrically conductive material, such as a metal, e.g., copper, to provide a via. Thereafter, a deposition, pattern and fill sequence is repeated to forms lines. This may be referred to a single damascene method for forming lines and vias. However, dual damascene sequences are also applicable. The sequence of deposition, pattern and etch are repeated as many times as needed to form each level of metal lines and vias. The metal lines and vias 32 depicted in FIG. 12 provide for electrical communication with the second memory cell 15. The electrical pathway for communication to the second memory cell is depicted in FIG. 14. FIG. 14 illustrates operation of current path for the first memory cell 10.

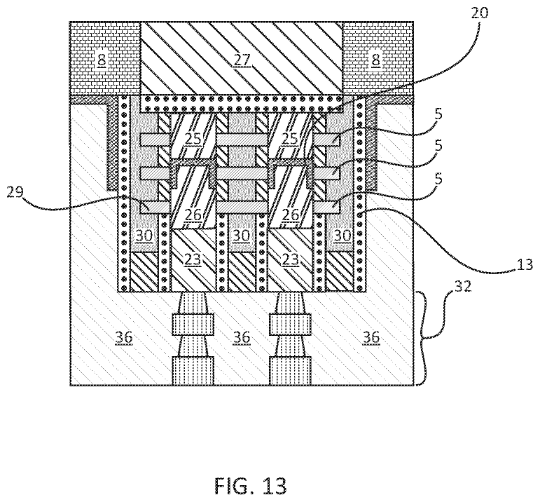

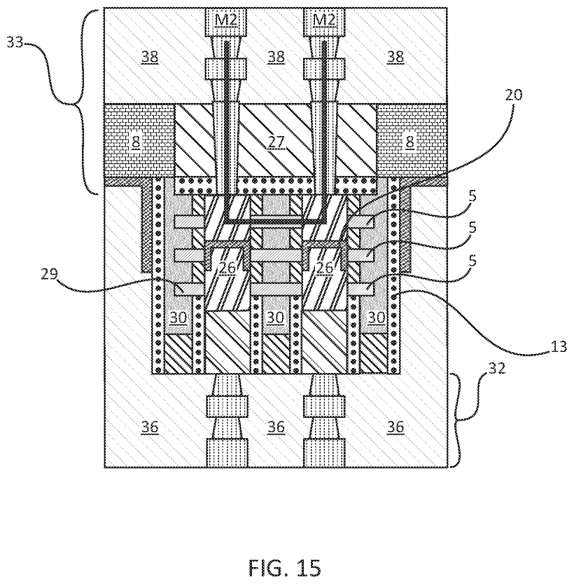

FIG. 13 illustrates one embodiment of flipping the structure depicted in FIG. 12, removing the supporting substrate 1, and forming an interlevel dielectric layer 27 through which the electrical communication structures to the first memory cell 10 are ultimately formed. The interlevel dielectric layer 27 may be formed using a deposition process, such as chemical vapor deposition (CVD) or spin on deposition (SOD). The composition of the interlevel dielectric layer 27 can be similar to the dielectric compositions described for the interlevel dielectric layer identified by reference number 36. The supporting substrate 1 is removed using a planarization process in combination with a selective etch process. Thereafter, an interlevel dielectric layer 27 is then etched to form via openings to the source and drain regions 25 of the first memory cell 10. An optional dielectric layer identified by reference number 38 may be formed atop the interlevel dielectric layer 27. Thereafter, the via openings are then filled with an electrically conductive material, such as a metal, e.g., copper, to provide a via. Thereafter, a deposition, pattern and fill sequence is repeated to forms lines. This may be referred to a single damascene method for forming lines and vias. However, dual damascene sequences are also applicable. The sequence of deposition, pattern and etch are repeated as many times as needed to form each level of metal lines and vias. The metal lines and vias 33 depicted in FIG. 14 provide for electrical communication with the first memory cell 10. The electrical pathway for communication to the first memory cell 10 is depicted in FIG. 15.

Having described preferred embodiments of a methods and structures for nanowire NOR flash memory with separated source/drain and backside contacts are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A memory device comprising:
a stack of nanostructures;
a first plurality of nanosheets from the stack of nanostructures having first source and drain regions at their opposing ends to position first channel regions for a first memory cell;
a second plurality of nanosheets from the stack of nanostructures having second source and drain regions at their opposing ends to position second channel regions for a second memory cell;
an isolation liner layer between the first source and drain regions and the second source and drain regions; and
a shared gate all around (GAA) control gate for the first and second memory cells, the shared gate all around (GAA) control gate including tunnel dielectric layer on the first and second channel regions, a trap dielectric layer on the tunnel dielectric layer, and a control conductor on the trap dielectric layer.

2. The memory device of claim 1, wherein a first set of electrically conductive structures extend from a first end of the memory device to the first memory cell.

3. The memory device of claim 2, wherein a second set of electrically conductive structures extend from a second end of the memory device to the second memory cell, wherein the first end and second end are on opposing sides of the memory device.

4. The memory device of claim 1, wherein the shared gate all around (GAA) device further comprises a blocking oxide layer between the trap dielectric layer and the control conductor.

5. The memory device of claim 1, wherein the tunnel dielectric layer is an oxide, and the trap dielectric layer is a nitride.

6. The memory device of claim 1, wherein the memory device is a NOR flash memory device.

7. A memory device comprising:
a stack of nanostructures;
a first plurality of nanowires from the stack of nanostructures having first source and drain regions at their opposing ends to position first channel regions for a first memory cell;
a second plurality of nanowires from the stack of nanostructures having second source and drain regions at their opposing ends to position second channel regions for a second memory cell;
an isolation liner layer between the first source and drain regions and the second source and drain regions; and
a shared gate all around (GAA) control gate for the first and second memory cells, the shared gate all around (GAA) control gate including tunnel dielectric layer on the first and second channel regions, a trap dielectric layer on the tunnel dielectric layer, and a control conductor on the trap dielectric layer.

8. The memory device of claim 7, wherein a first set of electrically conductive structures extend from a first end of the memory device to the first memory cell.

9. The memory device of claim 8, wherein a second set of electrically conductive structures extend from a second end of the memory device to the second memory cell, wherein the first end and second end are on opposing sides of the memory device.

10. The memory device of claim 7, wherein the shared gate all around (GAA) device further comprises a blocking oxide layer between the trap dielectric layer and the control conductor.

11. The memory device of claim 7, wherein the tunnel dielectric layer is an oxide, and the trap dielectric layer is a nitride.

12. The memory device of claim 7, wherein the memory device is a NOR flash memory device.

13. A method of forming a memory device comprising:
forming a replacement gate structure on a channel portion of a stack of semiconductor material layers;
forming trenches in a stack of semiconductor material layers, wherein the channel portion of the stack of semiconductor material layers is between the trenches;
forming a first source and drain semiconductor material at a first height in the trenches in contact with a first set of nanostructures of the stack of semiconductor material layers for a first memory cell;
forming an isolation layer on the first source and drain semiconductor material that is at the first height;
forming a second source and drain semiconductor material at a second height in the trenches in contact with a second set of nanostructures of the stack of semiconductor material layers for a second memory cell; and
substituting the replacement gate structure with a shared gate all around (GAA) control gate for the first and second memory cell, the shared gate all around (GAA) control gate including tunnel dielectric layer on the channel portion of the stack of nanostructures, a trap dielectric layer on the tunnel dielectric layer, and a control conductor on the trap dielectric layer.

14. The method of claim 13, wherein the first set of nanostructures and the second set of nanostructures are nanosheets.

15. The method of claim 13, wherein the first set of nanostructures and the second set of nanostructures are nanowires.

16. The method of claim 13 further comprising forming a first set of electrically conductive structures extend from a first end of the memory device to the first memory cell.

17. The method of claim 13 further comprising forming a second set of electrically conductive structures extend from a second end of the memory device to the second memory cell, wherein a first end and second end are on opposing sides of the memory device.

18. The method of claim 13, wherein the shared gate all around (GAA) device further comprises a blocking oxide layer between the trap dielectric layer and the control conductor.

19. The method of claim 13, wherein the tunnel dielectric layer is an oxide, and the trap dielectric layer is a nitride.

20. The method of claim 13, wherein the memory device is a NOR flash memory device.
